(19) United States
(12) Patent Application Publication
(10) Pub. No.: US 2015/0236292 A1
(43) Pub. Date: Aug. 20, 2015

(54) ORGANIC ELECTROLUMINESCENT ELEMENT AND ILLUMINATING APPARATUS

(71) Applicant: PANASONIC CORPORATION, Osaka (JP)

(72) Inventors: Toshihiko Sato, Osaka (JP); Yoshiharu Sanagawa, Osaka (JP)

(73) Assignee: PANASONIC INTELLECTUAL PROPERTY MANAGEMENT CO., LTD., Osaka-shi (JP)

(21) Appl. No.: 14/434,264

(22) PCT Filed: Oct. 10, 2013
(86) PCT No.: PCT/JP2013/006037

§ 371 Date: Apr. 8, 2015

(30) Foreign Application Priority Data
Oct. 11, 2012 (JP) 2012-225951

(51) Int. Cl. H01L 51/52; H01L 27/32; H01L 51/50

(52) U.S. Cl. CPC H01L 51/524; H01L 51/5012; H01L 27/3276; H01L 27/3258; H01L 51/5203

(57) ABSTRACT

An organic electroluminescent element includes: a substrate; an organic light emitter including a first electrode, an organic light-emitting layer, and a second electrode; and a sealing member covering the organic light emitter. The first electrode, the organic light-emitting layer and the second electrode are located in this order. An electrode lead-out part is provided on a surface of an end of the substrate. The electrode lead-out part is externally led out from the sealing member. A wiring board is provided on an opposite side of the sealing member from the substrate. The wiring board has a surface which a wiring connecting electrode is in. The wiring board includes an external electrode pad electrically connected to the wiring connecting electrode. The wiring connecting electrode and the electrode lead-out part are electrically connected to each other by a coating-type conductive material.

### TECHNICAL FIELD

The present invention relates to an organic electroluminescent element and an illuminating apparatus.

### BACKGROUND ART

An organic electroluminescent element (hereinafter, referred to also as “an organic EL element”) has been recently adapted to applications such as a lighting panel or the like. There is known an organic EL element in which an optically-transparent first electrode (positive electrode), an organic layer, and a second electrode (negative electrode) are stacked on a surface of an optically-transparent substrate in this order. The organic layer includes a plurality of layers including a light-emitting layer. Applying a voltage between the positive electrode and the negative electrode makes the light-emitting layer generate light in the organic EL element, and the light is extracted out through the optically-transparent electrode and substrate.

### PRIOR ART DOCUMENTS

### Patent Literature

Patent literature 1: JP 2009-217984 A

### SUMMARY OF THE INVENTION

### Problems to be Resolved by the Invention

FIGS. 11A to 11C show an example of a conventional organic EL element. In the organic EL element, an organic light emitter 10 is formed on a surface of a substrate 1. The organic light emitter 10 includes a first electrode 7, an organic light-emitting layer 8, and a second electrode 9 formed in this order. The organic light emitter 10 is covered and sealed with a sealing member 2 sticking to the substrate 1. A light emitting region is a region where the first electrode 7, the organic light-emitting layer 8, and the second electrode 9 are overlapped in planar view when the organic EL element is seen from a direction perpendicular to the surface of the substrate 1. A sealing region is a region which is formed by the disposition of the sealing member 2 in planar view. In FIG. 11B, the light emitting region is represented by a region P. In FIG. 11A, the sealed region is represented by a region Q, and a sealing outer region which is a region outside the sealed region is represented by a region T.

As shown in FIGS. 11B and 11C, in the organic EL element, a transparent conductive layer is formed as a patterned conductive layer on the surface of the substrate 1. A middle region of the conductive layer as the patterned conductive layer serves as the first electrode 7. The organic light emitter 10 is formed by stacking the organic light-emitting layer 8 and the second electrode 9 on a surface of the first electrode 7. The organic light emitter 10 is sealed with the sealing member 2. In FIG. 11B, a peripheral end of the sealing member 2 is shown by a two-dot chain line X.

Herein, in order to supply electricity to the organic light-emitting layer 8 via the first electrode 7 and the second electrode 9, the organic EL element generally includes an electrode lead-out part 5 on an end of the organic EL element, which is electrically connected to each electrode and is given electricity. The electrode lead-out part 5 includes a first electrode lead-out part 5a electrically connected to the first electrode 7, and a second electrode lead-out part 5b electrically connected to the second electrode 9. In FIG. 11C, for the purpose of clarity of the element structure, an end of the first electrode lead-out part 5a is shown on a right side, and an end of the second electrode lead-out part 5b is shown on a left side.

An extraction electrode 30 is formed on a surface of each electrode lead-out part 5. The extraction electrode 30 is provided in the sealing outer region (region T) protruding from the sealing member 2 on the surface of the substrate 1. A power can be supplied to the organic light-emitting layer 8 by connecting an external power source to the extraction electrode 30. The extraction electrode 30 is an electrode terminal for connection with the external power source, and has high conductivity and durability against electrical connection such as wire bondability. Connectivity with the external power source can be improved by the extraction electrode 30.

However, when the extraction electrode 30 is disposed to an end of the substrate, the extraction electrode 30 gives a non-light emitting region, which causes an increase in a ratio of the non-light emitting region. In addition, electrical connection such as wire bonding connection makes it necessary to secure a certain region area in the extraction electrode 30, which makes it difficult to decrease a width of the extraction electrode 30. When a space of a peripheral part is occupied by the extraction electrode 30, the non-light emitting region is formed in a frame shape in an outer periphery of the organic EL element. Increase in a ratio of the non-light emitting region makes an in-plane light emitting ratio in the whole area of the organic EL element decreased, and may cause a decrease in an in-plane effective light emitting ratio.

Patent Literature 1 discloses a technique of increasing a light emitting area of an organic EL element. The organic EL element has a structure in which an external terminal is inserted into a hole formed in a sealing plate to be connected to an electrode. However, the method of Patent Literature 1 requires to form the hole in the sealing plate and further insert the external terminal into the hole, which causes a problem that the element cannot be simply produced. Because a non-light emitting region is formed outside the hole of the sealing plate, a light emitting region cannot be sufficiently increased.

The present invention has been achieved in view of the above circumstances, and an object thereof is to provide an organic electroluminescent element which has a high light emitting area ratio and excellent connection reliability, and is easily produced, and an illuminating apparatus.

### Means of Solving the Problems

An organic electroluminescent element according to the present invention includes: a substrate; an organic light emitter including a first electrode, an organic light-emitting layer, and a second electrode; and a sealing member covering the organic light emitter. The first electrode, the organic light-emitting layer and the second electrode are located in this order. An electrode lead-out part provided on a surface of an end of the substrate is externally led out from the sealing member. The electrode lead-out part is electrically connected to at least one of the first electrode and the second electrode. A wiring board is provided on an opposite side of the sealing member from the substrate. The wiring board has a surface facing the substrate. The wiring board includes a wiring connecting electrode in the surface. The wiring connecting electrode faces the electrode lead-out part. The wiring board has an opposite surface from the surface which the wiring connecting electrode is in. The wiring board includes an external electrode pad in the opposite surface. The external electrode pad is electrically connected to the wiring connecting electrode. The wiring connecting electrode and the electrode lead-out part are electrically connected to each other by a coating-type conductive material.

In a preferable aspect of the organic electroluminescent element, a cured portion provided by curing the coating-type conductive material includes at least one projection laterally swelling.

In a preferable aspect of the organic electroluminescent element, the at least one projection includes a plurality of projections in a thickness direction of the organic electroluminescent element.

In a preferable aspect of the organic electroluminescent element, the at least one projection includes a projection in a thickness direction of the organic electroluminescent element, and a vertex of the projection is within 20% of a distance between the substrate and the wiring board from a middle of the distance.

In a preferable aspect of the organic electroluminescent element, the at least one projection is inside an end edge of a contact portion between the cured portion of the coating-type conductive material and the wiring connecting electrode, and inside an end edge of a contact portion between the dured portion of the coating-type conductive material and the electrode lead-out part.

In a preferable aspect of the organic electroluminescent element, the cured portion of the coating-type conductive material includes a boundary portion brought into contact with the wiring connecting electrode at an acute inclination angle and a boundary portion brought into contact with the electrode lead-out part at an acute inclination angle.

In a preferable aspect, the organic electroluminescent element further includes an insulating wall outside the electrode lead-out part on the substrate.

In a preferable aspect of the organic electroluminescent element, the cured portion of the coating-type conductive material is coated with a protector made of a resin.

In a preferable aspect, the organic electroluminescent element further includes an insulating sheet sticking to a side part of at least one of the substrate and the wiring board, and covering a side of the cured portion of the coating-type conductive material.

An illuminating apparatus according to the present invention includes the organic electroluminescent element.

### Effect of the Invention

The present invention can provide an organic electroluminescent element which has a high light emitting area ratio and excellent connection reliability, and is easily produced, and an illuminating apparatus.

### BRIEF DESCRIPTION OF DRAWINGS

FIG. 1A is an exploded perspective view of an example of an organic electroluminescent element in an embodiment;

FIG. 1B is a sectional view of an example of the organic electroluminescent element in the embodiment;

FIG. 2A is an enlarged sectional view of an example of the organic electroluminescent element in the embodiment;

FIG. 2B is an enlarged sectional view of an example of a wiring board used for the organic electroluminescent element;

FIG. 3 is an enlarged sectional view of an example of the organic electroluminescent element in the embodiment;

FIG. 4 is an enlarged sectional view of an example of the organic electroluminescent element in the embodiment;

FIG. 5 is an enlarged sectional view of an example of the organic electroluminescent element in the embodiment;

FIG. 6 is an enlarged sectional view of an example of the organic electroluminescent element in the embodiment;

FIG. 7 is an enlarged sectional view of an example of the organic electroluminescent element in the embodiment;

FIG. 8 is an enlarged sectional view of an example of the organic electroluminescent element in the embodiment;

FIG. 9A is a plan view of an example of the organic electroluminescent element in the embodiment;

FIG. 9B is a plan view of an example of the organic electroluminescent element in the embodiment;

FIG. 9C is a plan view of an example of the organic electroluminescent element in the embodiment;

FIG. 9D is a plan view of an example of the organic electroluminescent element in the embodiment;

FIG. 10A is a plan view of an example of the organic electroluminescent element in the embodiment;

FIG. 10B is a plan view of an example of the organic electroluminescent element in the embodiment;

FIG. 10C is a plan view of an example of the organic electroluminescent element in the embodiment;

FIG. 10D is a plan view of an example of the organic electroluminescent element in the embodiment;

FIG. 11A is a plan view of an example of a conventional organic electroluminescent element;

FIG. 11B is a exploded plan view of the example of the conventional organic electroluminescent element; and

FIG. 11C is a sectional view of the example of the conventional organic electroluminescent element.

### DESCRIPTION OF EMBODIMENTS

An organic electroluminescent element (an organic EL element) according to the present invention includes: a substrate 1; an organic light emitter 10 including a first electrode 7, an organic light-emitting layer 8, and a second electrode 9; and a sealing member 2 covering the organic light emitter 10. The first electrode 7, the organic light-emitting layer 8 and the second electrode 9 are located in this order. An electrode lead-out part 5 provided on a surface of an end of the substrate 1 is externally led out from the sealing member 2. The electrode lead-out part 5 is electrically connected to at least one of the first electrode 7 and the second electrode 9. A wiring board 4 is provided on an opposite side of the sealing member 2 from the substrate 1. The wiring board 4 has a surface facing the substrate 1. The wiring board 4 includes a wiring connecting electrode 11 in the surface. The wiring connecting electrode 11 faces the electrode lead-out part 5. The wiring board 4 has an opposite surface from the surface which the wiring connecting electrode 11 is in. The wiring board 4 includes an external electrode pad 12 in the opposite surface. The external electrode pad 12 is electrically connected to the wiring connecting electrode 11. The wiring connecting electrode 11 and the electrode lead-out part 5 are electrically connected to each other by a coating-type conductive material 3.

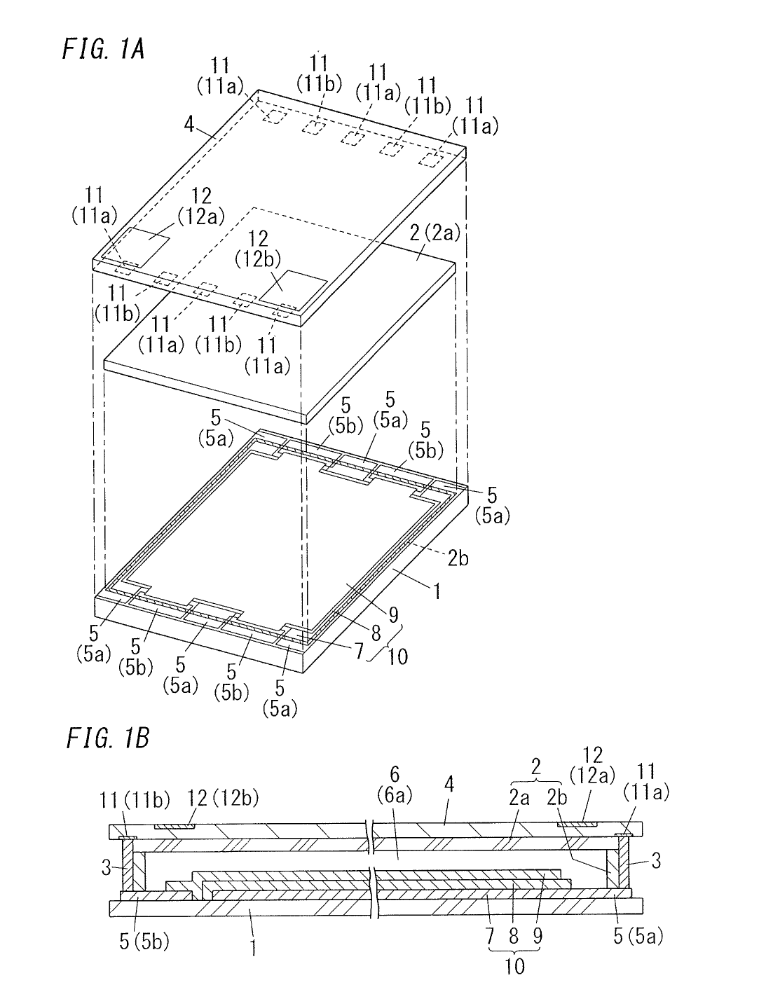

FIG. 1 shows an example of an organic electroluminescent element (organic EL element) in an embodiment. FIGS. 1A and 1B are collectively referred to as FIG. 1. FIG. 1A is an exploded view and shows a substrate 1 on which an organic light emitter 10 is formed, a sealing member 2 sealing the organic light emitter 10, and a wiring board 4 having one surface which an external electrode pad 12 is in and the other surface which a wiring connecting electrode 11 is in. A region of a sealing wall 2b serving as a wall of the sealing member 2 is indicated by oblique lines. In the sectional view of FIG. 1B, for the purpose of clarity of an element structure, an end of a first electrode lead-out part 5a is shown on the right side, and an end of a second electrode lead-out part 5b is shown on the left side.

As shown in FIG. 1, the organic EL element includes the organic light emitter 10 which is formed on a surface of the substrate 1. The organic light emitter 10 includes the first electrode 7, the organic light-emitting layer 8, and the second electrode 9. The first electrode 7, the organic light-emitting layer 8 and the second electrode 9 are located in this order. The organic light emitter 10 is covered and sealed with the sealing member 2 sticking to the substrate 1. The organic EL element includes the electrode lead-out part 5 on a surface of an end of the substrate 1, which is externally led out from the sealing member 2. The electrode lead-out part 5 is electrically connected to at least one of the first electrode 7 and the second electrode 9. The wiring board 4 is provided on an opposite side of the sealing member 2 from the substrate 1. The wiring board 4 has a surface facing the substrate 1. The wiring board 4 includes the wiring connecting electrode 11 in the surface. The wiring connecting electrode 11 faces the electrode lead-out part 5. The wiring board 4 has an opposite surface from the surface which the wiring connecting electrode 11 is in. The wiring board 4 includes the external electrode pad 12 in the opposite surface. The external electrode pad 12 is electrically connected to the wiring connecting electrode 11. The wiring connecting electrode 11 and the electrode lead-out part 5 are electrically connected to each other by the coating-type conductive material 3.

Since the electrode lead-out part 5 is connected to the wiring connecting electrode 11 by the coating-type conductive material 3 in the present form, it is not necessary to form a space in which an electrode (extraction electrode) to be taken out to the outside is provided on the end of the substrate. Therefore, decrease in a width of a sealing outer region can make a ratio of a non-light emitting region of a peripheral part decreased to increase a ratio of a light emitting region. This can increase a ratio of a light emitting area of the element. The wiring connecting electrode 11 is electrically conducted to the external electrode pad 12 by the wiring board 4. The external electrode pad 12 is in the opposite surface from the surface which the wiring connecting electrode 11 is in, i.e., an opposite surface from a light extraction surface. This can provide easy connection with external wiring, and connection having high conductivity. Since the electrode lead-out part 5 and the wiring connecting electrode 11 are electrically connected to each other by the coating-type conductive material 3, electrical conductivity between the electrode lead-out part 5 and the wiring connecting electrode 11 can be highly secured. Because the external electrode pad 12 can be formed according to a patterned conductive part of the wiring board 4, and the coating-type conductive material 3 provides electrical connection, the external electrode pad 12 functioning as the electrode (extraction electrode) for being connected to an external power source to supply electric power can be easily formed in the organic EL element. As a result, the organic EL element of the present form has a high light emitting area ratio and excellent connection reliability, and is easily produced. Hereinafter, the organic EL element of the present form will be further described.

The substrate 1 preferably has light transmitting property. The substrate 1 may be transparent. A glass substrate and a resin substrate or the like can be used as the substrate 1. When the substrate 1 is the glass substrate, moisture can be prevented from penetrating inside a sealing region because glass has low moisture permeability. A light extraction layer may be provided between the surface of the substrate 1 and the first electrode 7. Light extraction efficiency can be increased by providing the light extraction layer. The light extraction layer may be formed of a resin layer having a refractive index higher than that of glass, a resin layer containing light scattering particles, and high refractive index glass or the like. In the present form, the substrate 1 has a rectangular shape.

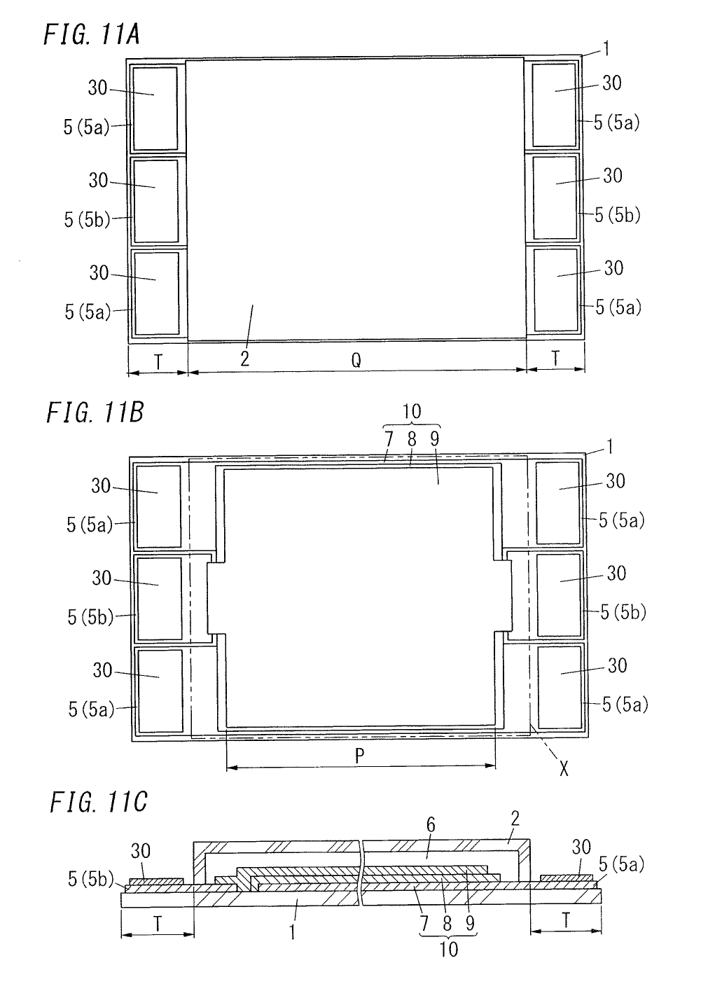

The organic light emitter 10 is a stacked product including the first electrode 7, the organic light-emitting layer 8, and the second electrode 9. The organic light emitter 10 is provided in a middle region of the substrate 1 in planar view (as seen from a direction perpendicular to the surface of the substrate). The organic EL element has a light emitting region in which the organic light emitter 10 is provided in planar view (see a region P of FIG. 11B as a reference).

The first electrode 7 and the second electrode 9 are paired with each other. One of the electrodes is a positive electrode, and the other is a negative electrode. In the present form, the first electrode 7 may be the positive electrode, and the second electrode 9 may be the negative electrode, but may be reversed. The first electrode 7 preferably has light transmitting property. In such a case, the first electrode 7 is a light extraction side electrode. The first electrode 7 may include a transparent conductive layer. Examples of materials for the conductive layer include ITO and IZO. The second electrode 9 may have light reflectivity. In such a case, light emitted from the light-emitting layer toward the second electrode 9 can be reflected with the second electrode 9, and the reflected light can be extracted out through the substrate 1. The second electrode 9 may have optical transparency. When the second electrode 9 has light transmitting property, light can be extracted out through the second electrode 9 and the sealing member 2. Alternatively, when the second electrode 9 has light transmitting property, a light reflective layer can be provided on the second electrode 9 and be located on an opposite side of the second electrode 9 from the organic light-emitting layer 8. Thereby, light traveling toward the second electrode 9 can be reflected, and the light can be extracted out through the substrate 1. The second electrode 9 can be made of, for example, Al and Ag or the like. The film thicknesses of the first electrode 7 and the second electrode 9 are not particularly limited, and may be, for example, about 10 to about 300 nm.

The organic light-emitting layer 8 has a function for generating light, and includes a plurality of functional layers appropriately selected from a hole injection layer, a hole transport layer, a light-emitting layer (a layer containing a light-emitting material), an electron transport layer, an electron injection layer, and an intermediate layer or the like. The thickness of the organic light-emitting layer 8 is not particularly limited, and may be, for example, about 60 to 300 nm.

Applying a voltage between the first electrode 7 and the second electrode 9 makes holes and electrons combine in the light-emitting layer (light emitting material-containing layer) and generates light of the organic EL element. It is accordingly necessary to lead out the electrodes respectively electrically conducted to the first electrode 7 and the second electrode 9 on the end of the substrate. The led-out electrodes are electrically conducted to the external electrode pad 12 which is a terminal to be electrically connected to external electrodes. In the present form, the electrode lead-out part 5 electrically conducted to the first electrode 7 and the second electrode 9 is provided on the surface of the substrate 1. A voltage can be applied to the light-emitting layer through them.

The electrode lead-out part 5 is formed on the surface of the end of the substrate 1. The electrode lead-out part 5 includes a first electrode lead-out part 5a electrically conducted to the first electrode 7 and a second electrode lead-out part 5b electrically conducted to the second electrode 9. In the present form, the electrode lead-out part 5 is formed of the conductive layer forming the first electrode 7.

The first electrode lead-out part 5a is formed by leading out the conductive layer forming the first electrode 7 without dividing the conductive layer on the end of the substrate 1, and extending the conductive layer toward the outside. More specifically, the conductive layer forming the first electrode 7 is formed on the end of the substrate 1 in a state where the conductive layer protrudes from the sealing member 2 in a place of the first electrode lead-out part 5a The first electrode lead-out part 5a is electrically conducted to the first electrode 7 and externally extends from the sealing region, which makes it possible to electrically connect the outside of the sealing region and the inside of the element to each other. Thus, the first electrode lead-out part 5a can be easily formed by extending the first electrode 7.

In the present form, the second electrode lead-out part 5b is disposed separately from the first electrode 7 by separating part of the conductive layer forming the first electrode 7, leading out the conductive layer toward the end of the substrate 1, and externally extending the conductive layer. More specifically, the conductive layer forming the second electrode lead-out part 5b is separated from the first electrode 7, and formed also on the end of the substrate 1 in a state where the conductive layer protrudes from the sealing member 2. The second electrode lead-out part 5b is electrically conducted to the second electrode 9 and externally extends from the sealing region, which makes it possible to electrically connect the outside of the sealing region and the inside of the element to each other. When the second electrode lead-out part 5b is formed of the patterned conductive layer, the second electrode lead-out part 5b can be easily formed. In the element, the second electrode lead-out. part 5b is in contact with the stacked second electrode 9, and thereby the second electrode lead-out part 5b and the second electrode 9 are electrically conducted to each other.

Although FIG. 1 shows a form in which the electrode lead-out part 5 is formed in a range slightly smaller than a peripheral end edge of the substrate 1, the electrode lead-out part 5 may extend to an end edge of the substrate 1. When an end edge of the electrode lead-out part 5 is located at the end edge of the substrate 1, the sealing outer region can be further decreased, and the non-light emitting region of the end of the substrate can be further decreased. An illuminating apparatus can be formed by arranging a plurality of organic EL elements in a planar form. In such an illuminating apparatus, the electrode lead-out part 5 on the end edge of the substrate 1 can connect one organic EL element to other organic EL elements easily and electrically with electrical conduction at necessary places. As in the present form, there is also preferred a structure in which the electrode lead-out part 5 is not formed on the end edge of the substrate 1. When the organic EL elements are arranged in a planar form if the electrode lead-out part 5 is not formed on the end edge of the substrate 1, an insulating distance between the adjacent organic EL elements can be secured, and short failure can be suppressed.

The first electrode 7, the first electrode lead-out part 5a, and the second electrode lead-out part 5b may be formed of the same conductive material. Thereby, the organic EL element can be easily manufactured. The conductive layer of the first electrode 7 may be made of, for example, a transparent metal oxide. Specifically, for example, the conductive layer may be made of ITO. The thickness of the conductive layer is not particularly limited, and may be within a range of 0.01 to 0.5 μm. Preferably, the thickness of the conductive layer can be, for example, about 0.1 to 0.2 μm.

In the present form, the sealing member 2 includes a plate-like sealing substrate 2a facing the substrate 1 and having a flat surface, and a sealing wall 2b provided between the substrate 1 and the sealing substrate 2a on a peripheral part of the sealing substrate 2a.

The sealing substrate 2a can be formed of a substrate material having low moisture permeability. For example, a glass substrate can be used as the sealing substrate 2a. The use of the glass substrate can suppress moisture infiltration. When the substrate having a flat surface is used as the sealing substrate 2a as in the present form, a recess for storing the organic light emitter 10 is not required, and the organic light emitter 10 can be easily sealed.

The sealing wall 2b may be made of a sealing resin material. A thermosetting or photo-curing resin composition may be used as the sealing resin material. The sealing resin material preferably contains a drying agent. The sealing resin material preferably has adhesiveness. In such a case, the sealing substrate 2a can stick to the substrate 1 with the sealing resin material interposed between the sealing substrate 2a and the substrate 1. The sealing wall 2b is thicker than the organic light emitter 10. Thereby, a space corresponding to a thickness of the organic light emitter 10 can be secured, and the organic light emitter 10 can be sealed with the flat sealing substrate 2a. The sealing wall 2b can be provided in a region surrounding an outer periphery of the organic light emitter 10. Therefore, the sealing substrate 2a sticks to the entire outer periphery of the substrate 1 and the organic light emitter 10 can be sealed with high sealability and be blocked from the outside. When the sealing wall 2b is made of a resin, the thickness of the sealing wall 2b can be easily adjusted. Therefore, because of the easy adjustment of the height of the sealing member 2, the height of the sealing member 2 can be adjusted to a height for securement of electrical conductivity which the coating-type conductive material 3 gives.

A sealing clearance 6 is provided inside the sealing member 2 by sealing the organic light emitter 10 with the sealing member 2. In the organic EL element of the present form, the sealing clearance 6 may be filled with a sealing filler 6a, to provide the organic EL element with a filling-sealing structure. When the sealing clearance 6 is filled with the sealing filler 6a, the filler may contain a drying agent. Thereby, even if moisture infiltrates into the element, the filler can absorb the infiltrating moisture. Preferably, the filler contains a drying agent and has adhesiveness. The sealing wall 2b can serve as a so-called “dam layer” damming the filler when the sealing clearance 6 is filled with the filler.

In the organic EL element, the sealing substrate 2a may have a storing recess to store the organic light emitter 10, and the organic light emitter 10 is stored in the storing recess. More specifically, the sealing substrate 2a itself is the sealing member 2. In this case, the sealing wall 2b may be part of the sealing substrate 2a and a side wall of the storing recess. The sealing substrate 2a is a so-called cap-like substrate. The use of the sealing substrate 2a having the storing recess can improve sealability of the side, and thereby the organic light emitter 10 can be sealed with excellent sealability. In such a case, the sealing member 2 can stick to the substrate 1 with a bonding material interposed between the sealing member 2 and the substrate 1. For example, a resinous bonding material can be used as the bonding material. The resinous bonding material preferably has a moisture-proof property. The resinous bonding material contains, for example, a drying agent, and thereby the moisture-proof property of the resinous bonding material can be improved. The resinous bonding material may contain a thermosetting resin and/or an ultraviolet curing resin or the like as principal components.

The organic EL element may have a hollow structure where the sealing clearance 6 is a cavity and gives a sealing space. For example, when the cap glass-like sealing member 2 (sealing substrate 2a) has a storing recess, the storing recess can give the cavity to form the sealing space. When the sealing clearance 6 is the sealing space, a drying material can be provided in the sealing space. Thereby, even if moisture infiltrating into the sealing space, the drying material can absorb the infiltrating moisture.

The organic EL element of the present form includes the wiring board 4 which includes the external electrode pad 12 and the wiring connecting electrode 11. The wiring board 4 is provided on the sealing member 2 and is located on an opposite side of the sealing member 2 from the organic light emitter 10, i.e., on a back side of the organic EL element. The wiring connecting electrode 11 and the electrode lead-out part 5 are electrically connected to each other by the coating-type conductive material 3.

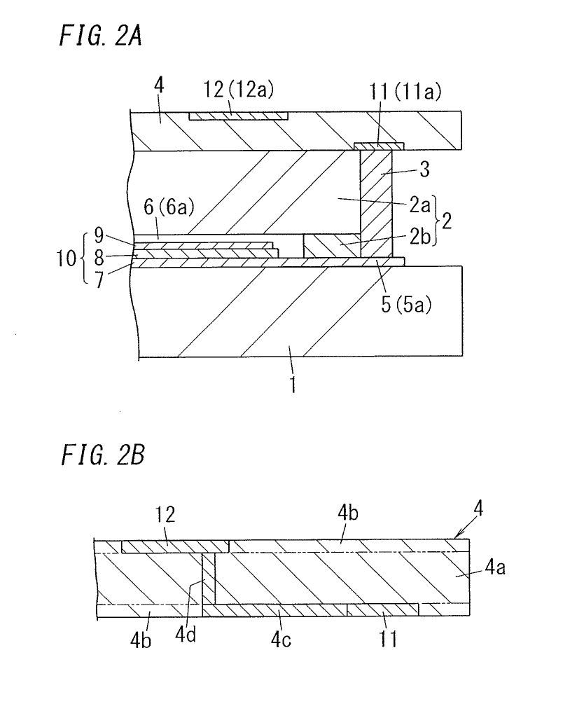

FIG. 2A shows an enlarged condition of a vicinity of the electrode lead-out part 5 (first electrode lead-out part 5a) of the organic EL element of FIG. 1. FIG. 2A shows the structure of the first electrode lead-out part 5a, and the second electrode lead-out part 5b may also have the same structure. FIG. 2B shows an example of the wiring board 4. FIGS. 2A and 2B are collectively referred to as FIG. 2. FIG. 2 schematically shows the element, and sizes of parts shown in FIG. 2 are different from those shown in FIG. 1.

The wiring board 4 sticks to a surface on an opposite side of the sealing member 2 from the substrate 1. Thus, the wiring board 4 including the external electrode pad 12 gives an electrode wiring extracted from the electrode lead-out part 5, and the external electrode pad 12 can be provided above the surface of the sealing member 2 merely by pasting the wiring board 4. Thereby, the external electrode pad 12 can be safely and easily provided. Since the external electrode pad 12 is provided in the wiring board 4, the external electrode pad 12 can be provided in an appropriate pattern, and a patterned circuit can be provided in the wiring board 4, which can provide an improvement in electric connectivity and an improvement in a degree of freedom of the patterned circuit. The external electrode pad 12 can connect to an external power source, improve durability against electrical connection such as wire bonding, and provide an improvement in connectivity with the external power source.

The wiring connecting electrode 11 and the external electrode pad 12 are electrically connected to the first electrode 7 or the second electrode 9 via the electrode lead-out parts 5. The wiring connecting electrode 11 includes a first wiring connecting electrode 11a, the external electrode pad 12 includes a first external electrode pad 12a, and a first wiring connecting electrode 11a and a first external electrode pad 12a are electrically conducted to the first electrode 7 via the first electrode lead-out part 5a. The wiring connecting electrode 11 includes a second wiring connecting electrode 11b, the external electrode pad 12 includes a second external electrode pad 12b, and a second wiring connecting electrode 11b and a second external electrode pad 12b are electrically conducted to the second electrode 9 via the second electrode lead-out part 5b. The first wiring connecting electrode 11a and the first external electrode pad 12a are electrically insulated from the second wiring connecting electrode 11b and the second external electrode pad 12b. Thereby, the electrode can be electrically connected with the outside.

An appropriate type of wiring board in which a conductive material layer is formed on a surface of an insulating layer 4a may be used as the wiring board 4. The wiring board 4 may be a printed-wiring board. The wiring board 4 may be a single layer board which has a circuit wiring on each surface of the insulating layer 4a, or a multilayer board which has a stacked structure of a plurality of single layer boards. The multilayer board enables complicated routing of wires. Meanwhile, the single layer board enables a reduction in a thickness of the wiring board 4.

FIG. 2B shows an example of a structure of a wiring board 4. The wiring board 4 includes a conductive material which is stacked on a surface of an insulating layer 4a. An external electrode pad 12 is formed on one surface of the insulating layer 4a. A wiring connecting electrode 11 is formed on the other surface of the insulating layer 4a. The wiring connecting electrode 11 and the external electrode pad 12 are electrically conducted to each other by a conductive wiring 4c linearly provided on the surface of the insulating layer 4a and a penetration wiring 4d penetrating the insulating layer 4a in a thickness direction of the wiring board 4. The wiring connecting electrode 11, the external electrode pad 12, the conductive wiring 4c, and the penetration wiring 4d may be made of the same conductive material. For example, they can be made of copper, nickel, and gold or the like. The wiring board 4 of the present form includes a resist layer 4b which is provided on the surface of the insulating layer 4a. The wiring connecting electrode 11 and the external electrode pad 12 are buried in the resist layer 4b. The resist layer 4b has a function as a resist when the wiring connecting electrode 11, the external electrode pad 12, and the conductive wiring 4c are formed in a desired pattern. The conductive material is easily stacked in a state where it is patterned by the resist layer 4b. The wiring connecting electrode 11 and the external electrode pad 12 in the wiring board 4 may be stacked in patterns of the wiring connecting electrode 11 and external electrode pad 12 as a target, or may be formed from the conductive layer which is on the surface and is processed through a patterning process like etching. The wiring board 4 may be formed from a cupper-clad laminate or the like.

In FIG. 2B, the penetration wiring 4d is at a position of the external electrode pad 12, and the conductive wiring 4c is in the surface of the wiring board 4 with the wiring connecting electrode 11. However, formation patterns of the conductive wiring 4c and penetration wiring 4d are not limited thereto. The conductive wiring 4c and the penetration wiring 4d can be formed in appropriate patterns to electrically connect the wiring connecting electrode 11 and the external electrode pad 12 to each other. For example, the conductive wiring 4c may be formed in the surface of the wiring board 4 in which the external electrode pad 12 is provided. The penetration wiring 4d may be provided at a position where the wiring connecting electrode 11 is formed, and at a position where the wiring connecting electrode 11 and the external electrode pad 12 are not formed. The conductive wiring 4c and the penetration wiring 4d can be provided not to short-circuit the first electrode 7 and the second electrode 9. For example, one part of the conductive wiring 4c which is a wiring part led out from the first electrode 7 may be formed on one surface of the insulating layer 4a, and the other part of the conductive wiring 4c which is a wiring part led out from the second electrode 9 may be formed on the other surface of the insulating layer 4a. In this case, two kinds of conductive wirings 4c can be insulated be crossed in plane view and be not brought into contact with each other. Respective led-out portions of the first electrode 7 and the second electrode 9 can be collected in the respective electrode pads without short circuiting the first electrode 7 and the second electrode 9.

The insulating layer 4a of the wiring board 4 may have a plate-like shape, and may be formed of an insulating material which is possible to cure. The wiring board 4 may be also preferably a flexible wiring board. When the wiring board is a flexible wiring board like a sheet-like wiring board, a wiring board capable of being curved or a wiring board capable of being wound up in a roll state, the wiring board 4 can be treated better and be more easily pasted. The wiring board 4 may be low temperature co-fired ceramics (LTCC). Thereby, the wiring board 4 can be efficiently obtained.

The wiring board 4 can be pasted on the surface of the sealing member 2 with a double-sided tape or an adhesive agent interposed between the wiring board 4 and the sealing member 2. The wiring board 4 is preferably pasted after sealing. The sealing member 2 (sealing substrate 2a) may previously attach the wiring board 4 before sealing the organic light emitter 10, followed by sealing the organic light emitter 10. However, the wiring board 4 can be more safely attached with higher manufacturability by performing pasting after sealing.

The wiring board 4 can be attached to the sealing member 2 in a state where an outer edge of the wiring board 4 protrudes from an outer edge of the sealing member 2. In such a case, the wiring connecting electrode 11 partially or wholly protrudes from the sealing member 2. Thereby, the wiring connecting electrode 11 is provided in the protruding portion of the wiring board 4, and thereby the wiring connecting electrode 11 and the electrode lead-out part 5 can be easily disposed to face each other. The wiring connecting electrode 11 is preferably provided at a position overlapping with a position where the electrode lead-out part 5 is provided in plane view. Thereby, the electrode lead-out part 5 and the wiring connecting electrode 11 can be easily disposed to face each other, and the coating-type conductive material 3 can easily provide electrical connection.

The external electrode pad 12 is electrically connected to the electrode lead-out part 5 with the wiring structure of the wiring board 4. In the present form, as shown in FIG. 1, the external electrode pad 12 includes the first external electrode pad 12a connected to a plurality of first wiring connecting electrodes 11a, and the second external electrode pad 12b connected to a plurality of second wiring connecting electrodes 11b. Thus, as a preferable form, the plurality of wiring connecting electrodes 11 are collected and integrated by the wiring structure of the wiring board 4 (conductive wiring 4c, penetration wiring 4d), to provide one or a small number of external electrode pads 12. Thereby, the number of power feeding points can be decreased, which can provide easy power feeding from the external power source.

As shown in FIG. 1, in the present form, the wiring board 4 is a rectangular wiring board and is larger than the sealing member 2 (sealing substrate 2a). Therefore, the wiring board 4 is pasted on the whole surface of the sealing member 2 so as to cover the sealing member 2. This can provide easy formation of the wiring board 4, and provides easy attachment of the wiring board 4 and easy routing of electrical wires (collection of the electrodes, or the like).

In the present form, the wiring connecting electrode 11 and the electrode lead-out part 5 facing each other are electrically connected by the coating-type conductive material 3. By the electrical connection through the coating-type conductive material 3, the coating-type conductive material 3 can be easily provided by coating, spraying or the like; the coating-type conductive material 3 can be firmly fixed by curing; and the electrical connection between the electrode lead-out part 5 and the wiring connecting electrode 11 can be easily provided at high conductivity. When the coating-type conductive material 3 provides the electrical connection, the width of the sealing outer region outside the sealing member 2 can be approximately set to a width required for the electrical connection by the coating-type conductive material 3. Therefore, the non-light emitting region outside the sealing member 2 can be decreased, and the ratio of the light emitting region in the organic EL element can be improved.

The coating-type conductive material is a coatable conductive material. The coating-type conductive material has flowability before the organic EL element is manufactured. After manufacturing the organic EL element, the coating-type conductive material may be cured in a solid state and provide conductive connection. The coating-type conductive material having flowability before the organic EL element is manufactured can be easily disposed. The coating-type conductive material is in a solid state after the organic EL element is manufactured, and thereby the coating-type conductive material can provide excellent conductive connection. The “coating-type” means that the conductive material can flow and be applied. A method for disposing the coating-type conductive material is not limited to applying. The coating-type conductive material may be a paste, a liquid, and a jelly or the like. The coating-type conductive material may contain a conductive material. The coating-type conductive material is cured to serve as a conductive cured body. The conductive cured body is defined as a conductive connection part.

The coating-type conductive material is not particularly limited, and can include one or more kinds selected from a solder, a conductive adhesive agent, a conductive paste, and a metal nano ink or the like, for example. Examples of the solder include a thread solder, a cream solder, and a solder paste. Examples of the solder further include a special solder. Examples of the special solder include “Cerasolzer” manufactured by Kuroda Techno Co., Ltd. Examples of the conductive adhesive agent include an adhesive Ag paste and an adhesive Cu paste. Examples of the conductive paste include an Ag paste, a Cu paste, and conductive pastes containing the Ag paste and/or Cu paste and dispersing agents or the like. Examples of the metal nano ink include an Ag nano ink. The Ag nano ink is an ink in which silver particles of nano order are dispersed. The conductive paste is preferably used as the coating-type conductive material. The conductive paste can easily provide conductive connection at high conductivity.

The coating-type conductive material 3 can be continuously provided in a thickness direction at a position where the wiring connecting electrode 11 and the electrode lead-out part 5 overlap each other in plane view. A position of the coating-type conductive material 3 in plane view may be the same through the thickness direction. The coating-type conductive material 3 is provided in the thickness direction, and thereby the electrode lead-out part 5 and the wiring connecting electrode 11 can be electrically conducted to each other at high conductivity. The coating-type conductive material 3 may be provided in contact with a side part (side surface) of the sealing member 2. The coating-type conductive material 3 is in contact with the side part of the sealing member 2, and accordingly the coating-type conductive material 3 is stable and can enhance conductive connectivity. In the case of the present form, the coating-type conductive material 3 contacts the sealing wall 2b.

Two kinds of coating-type conductive materials 3 are provided. One of the coating-type conductive materials 3 is provided between the first electrode lead-out part 5a and the first wiring connecting electrode 11a, and the other is provided between the second electrode lead-out part 5b and the second wiring connecting electrode 11b. Thereby, the electrodes can be led out without causing short circuit. The coating-type conductive materials 3 may be provided at two or more places on the side part of the sealing member 2.

A coating-type conductive material having thermosetting properties can be preferably used as the coating-type conductive material 3. In such a case, the coating-type conductive material 3 can be easily cured by thermal curing, to provide electrical connection. The conductive cured body is formed as a cured portion of the coating-type conductive material 3 on the side part of the sealing member 2 by curing the coating-type conductive material 3. The coating-type conductive material 3 may be a pasty material having flowability, and can be easily applied. In particular, the conductive paste is easily applied.

The conductive material contained in the coating-type conductive material 3 is not particularly limited, and metal particles can be preferably used. Examples of the metal particles include particles made of silver, gold, copper, and nickel or the like. Among these, a silver paste containing silver is preferable. The coating-type conductive material 3 may contain a binder. When the coating-type conductive material 3 contains the binder, viscosity and adhesiveness of the coating-type conductive material 3 can be adjusted, and thereby the coating-type conductive material 3 having high treating property can be obtained. The coating-type conductive material 3 may include a dispersed conductive material in a solvent or the like. The solvent may be an organic solvent or the like. The coating-type conductive material 3 can be easily cured by using an organic solvent evaporated during thermal curing. A thermal curing temperature of the coating-type conductive material 3 is not particularly limited, and can be, for example, 50° C. to 100° C. When the thermal curing temperature is too high, heat during curing may cause deterioration in the element.

The coating-type conductive material 3 is injected between the substrate 1 and the wiring board 4 from the side of the element after the wiring board 4 is pasted on the sealing member 2. Thereby, the wiring connecting electrode 11 in the wiring board 4 and the electrode lead-out part 5 on the surface of the substrate 1 can be easily electrically connected to each other.

A method for injecting the coating-type conductive material 3 into a clearance between the substrate 1 and the wiring board 4 is not particularly limited, and the coating-type conductive material 3 can be applied with a dispenser or the like. The coating-type conductive material 3 can be efficiently applied to a slight clearance between the substrate 1 and the wiring board 4 by the dispenser. Examples of the dispenser may include an air type dispenser, a screw type dispenser, and a jet type dispenser or the like A syringe type dispenser, which has a nozzle (needle tip) to be inserted between the substrate 1 and the wiring board 4, can extrude the coating-type conductive material 3 to discharge the coating-type conductive material 3 from a nozzle discharge port. A method inserting the nozzle into the clearance may make it difficult to control a tip position of the nozzle, which may make it impossible to easily discharge the coating-type conductive material 3. Therefore, there is more preferably used a dispenser which sprays and applies the coating-type conductive material 3 to the clearance between the substrate 1 and the wiring board 4 from the side of the element. For example, the jet type dispenser can control an injection amount, an injection velocity, and an injection position or the like with a high degree of accuracy, and apply the coating-type conductive material 3 by injecting, which is preferable.

After cured, the coating-type conductive material 3 has a flat outer surface, as shown in FIG. 2A as a preferable form. Thereby, the conductive cured body having the substantially same cross-sectional area in the thickness direction makes it possible to connect the electrode lead-out part 5 and the wiring connecting electrode 11 to each other, which can provide electrical connection at high conductivity. The flat side surface of the conductive cured body can suppress generation of cracks.

The organic EL element of the present form can be produced by the same method as a method of a usual organic EL element before a sealing process. For example, the organic light emitter 10 is formed by stacking the first electrode 7, the organic light-emitting layer 8, and the second electrode 9 on the surface of the substrate 1. And a sealing resin of the sealing wall 2b is disposed. Then, the organic light emitter 10 is sealed with the sealing member 2 by making the sealing substrate 2a stick to the sealing wall 2b. Needless to say, the organic light emitter 10 may be sealed with a sealing member 2 having a storing recess. In this case, the electrode lead-out part 5 can be formed by making an extending part of the first electrode 7 protrude from the sealing member 2.

Next, in the organic EL element of the present form, the wiring board 4 is pasted on the surface of the sealing member 2 with an adhesive agent or a double-sided tape or the like interposed between the wiring board 4 and the sealing member 2. In this case, an end of the wiring board 4 protrudes from the sealing member 2 to expose the wiring connecting electrode 11 to the outside. The coating-type conductive material 3 is injected to be applied to a place between the wiring connecting electrode 11 and the electrode lead-out part 5 by the jet type dispenser or the like from the side. The injected coating-type conductive material 3 adheres to a side wall surface of the sealing wall 2b, and spreads in the thickness direction so as to be brought into contact with both the wiring connecting electrode 11 and the electrode lead-out part 5. Needless to say, the coating-type conductive material 3 may be applied by dispensers other than the jet type dispenser, and other applicators. In short, the coating-type conductive material 3 may be provided so that the wiring connecting electrode 11 and the electrode lead-out part 5 are electrically connected to each other. Then, the coating-type conductive material 3 is cured by heating the coating-type conductive material 3 to a curing temperature of the coating-type conductive material 3. As described above, the organic EL element shown in FIG. 1 can be manufactured.

A planar light emitting device (illumination body) having a large light emitting area can be obtained by disposing a plurality of organic EL elements in a planar form. Since the non-light emitting region of the end of the substrate can be decreased in the organic EL element of the present form, a non-light emitting region formed in a boundary portion between the adjacent organic EL elements can be decreased, and a connection part between the organic EL elements can be made unnoticeable. Since the non-light emitting region is decreased, a light emitting ratio can be increased, and a light emitting device having large light emitting intensity can be obtained.

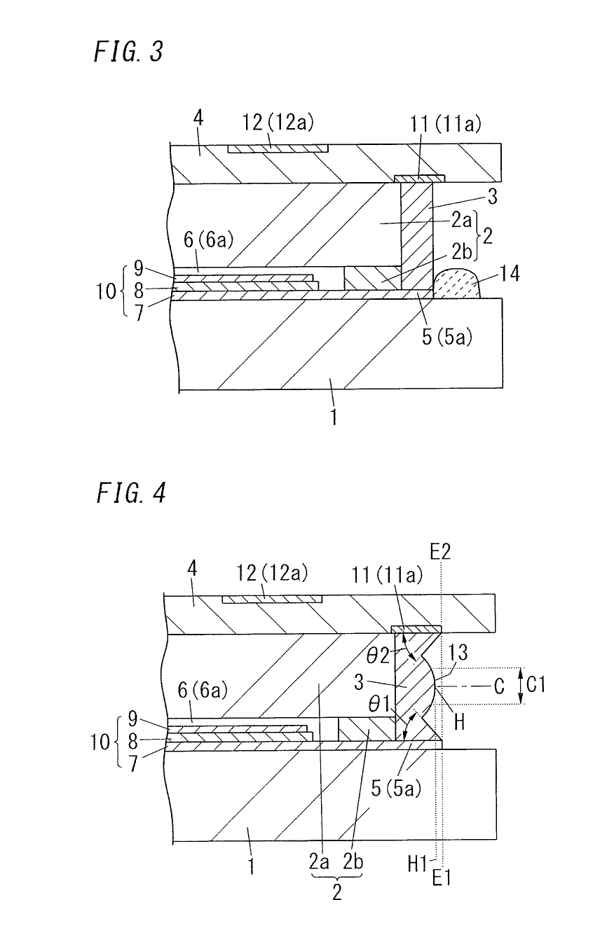

FIG. 3 shows another example of an organic EL element in an embodiment. FIG. 3 is an enlarged view of a vicinity of a position where a coating-type conductive material 3 connects an electrode lead-out part 5 and a wiring connecting electrode 11 to each other. The present form has the almost same structure as the structure of the form of FIGS. 1 and 2 except that an insulating wall 14 is provided.

In the present form, the insulating wall 14 having insulation properties is provided outside the electrode lead-out part 5 on a substrate 1. Thus, the insulating wall 14 can secure an insulating distance on a peripheral part of the organic EL element, and decrease insulation failure. A plurality of organic EL elements are often arranged in a linear or planar form. In such a case, if electrodes of adjacent elements are brought into contact with each other, the elements may be short-circuited. However, the insulating wall 14 secures the insulating distance, which can suppress short failure. By electrical connection through the coating-type conductive material 3, the coating-type conductive material 3 may flow out toward the outside because of the flowability. The insulating wall 14 can dam flow of the coating-type conductive material 3, and thereby the short failure can be more effectively suppressed. Particularly, when the coating-type conductive material 3 is applied to a side part surface of a sealing member 2 by injection, the injected coating-type conductive material 3 may laterally flow out by this energy. The insulating wall 14 can dam spread of the coating-type conductive material 3. The insulating wall 14 and the coating-type conductive material 3 (conductive cured body) may or may not be in contact with each other. When the coating-type conductive material 3 is cured in a state where outflow of the coating-type conductive material 3 is dammed, the insulating wall 14 and the conductive cured body are in contact with each other.

The insulating wall 14 preferably has a thickness (wall height) larger than a thickness of the electrode lead-out part 5. This can more reliably prevent the coating-type conductive material 3 from flowing out. The insulating wall 14 may be provided over a peripheral part of the substrate 1. Thereby, the flow of the coating-type conductive material 3 can be suppressed.

When the adjacent elements are electrically conducted to each other, the insulating wall 14 may not be partially or wholly provided in the electrically conducted portion. For example, the insulating wall 14 may be divided in the electrically conducted portion. In such a case, the electrode lead-out part 5 and/or the coating-type conductive material 3 may extend to an end edge of the substrate 1.

The insulating wall 14 may or may not be in contact with the electrode lead-out part 5. When the insulating wall 14 and the electrode lead-out part 5 are in contact with each other without any clearance, a ratio of a non-light emitting region can be decreased. Meanwhile, when the insulating wall 14 and the electrode lead-out part 5 are not in contact with each other and a clearance is provided between the insulating wall 14 and the electrode lead-out part 5, the flowing-out coating-type conductive material 3 can flow into the clearance, and be impounded. Therefore, the outflow of the coating-type conductive material 3 on the end can be further suppressed, and the insulation properties can be improved.

The insulating wall 14 may overlap with a surface of the electrode lead-out part 5 on an inner side. This can cause an increase in a thickness of the insulating wall 14 to further prevent the coating-type conductive material 3 from flowing out. The insulating wall 14 may be provided on the electrode lead-out part 5.

The insulating wall 14 can be made of an appropriate insulating material. For example, the insulating wall 14 can be made of a resin or the like. In such a case, the insulating wall 14 can be formed by applying an insulating resin to a surface of the substrate 1 by a dispenser or the like, and curing the insulating resin. Examples of the resin include an epoxy resin, an acrylic resin, a phenolic resin, polyolefin, and unsaturated polyester. Alternatively, the insulating wall 14 may be formed by pasting a linear resin body on a peripheral end of the substrate 1. When applied beside the insulating wall 14, the coating-type conductive material 3 abuts against the insulating wall 14, and is dammed, which prevents the coating-type conductive material 3 from flowing out to the outside. By curing the coating-type conductive material 3, the conductive cured body is completely formed in a state where the conductive cured body is in contact with the insulating wall 14.

The insulating wall 14 and the coating-type conductive material 3 may be simultaneously cured. For example, the insulating wall 14 is made of a resin material having shape holdability and a high viscosity, and the uncured insulating wall 14 dams the coating-type conductive material 3. Then, the insulating wall 14 and the coating-type conductive material 3 can be simultaneously cured by heating. Since thermal curing can be simultaneously performed in such a case, electrical connection can be efficiently provided. In this case, materials for the coating-type conductive material 3 and the insulating wall 14 are selected so that the coating-type conductive material 3 and the uncured insulating wall 14 are not mixed with each other. In order to more reliably suppress the outflow of the coating-type conductive material 3, the coating-type conductive material 3 is more preferably applied after the insulating wall 14 is cured.

The insulating wall 14 is preferably formed after sealing. Thereby, the insulating wall 14 can be easily provided without damaging the element. Needless to say, the insulating wall 14 may also be formed at an appropriate stage before the sealing is ended. For example, the insulating wall 14 may be formed on the surface of the substrate 1 before the first electrode 7 and the electrode lead-out part 5 are provided, or may be formed on the surface of the substrate 1 before an organic layer is stacked, after the electrode lead-out part 5 is provided. When provided after sealing, the insulating wall 14 may be formed before the wiring board 4 is pasted on the sealing member 2, or may be formed after the wiring board 4 is pasted on the sealing member 2. When the insulating wall 14 is formed before the wiring board 4 is pasted on the sealing member 2, the wiring board 4 can be in a state of not protruding to the side, and thereby the insulating wall 14 can be simply provided.

The form of FIG. 3 illustrates addition of the insulating wall 14 to the form of FIG. 2A, and the insulating wall 14 can be provided also in each below-mentioned form in which the coating-type conductive material 3 provides electrical connection. Also in such a case, the insulating wall 14 can secure the insulating distance and give an element having high conductive reliability.

FIG. 4 shows yet another example of an organic EL element in an embodiment. FIG. 4 is an enlarged view of a vicinity of a position of a coating-type conductive material 3 connecting an electrode lead-out part 5 and a wiring connecting electrode 11 to each other. The present form has the almost same structure as the structure of the form of FIGS. 1 and 2 except that the cured coating-type conductive material 3 has a different shape.

In the present form, the cured portion of the coating-type conductive material 3 includes a projection 13 laterally swelling. Thus, as a preferable form, the projection 13 is provided in a conductive cured body obtained by curing the coating-type conductive material 3. The coating-type conductive material 3 can be provided in a large width by providing the projection 13, and accordingly conductivity can be improved. The coating-type conductive material 3 without the projection may generate cracks (cleavages and flaws) by heat histories such as a heating process. On the other hands, the coating-type conductive material 3 with the projection 13 can be less likely to generate the cracks. Herein, in the organic EL element of the present form, the coating-type conductive material 3 is provided to connect a wiring board 4 which sticks to a sealing member 2 and a substrate 1 to each other. Therefore, the coating-type conductive material 3 is apt to be given a non-uniform stress and cracked due to a difference between coefficients of thermal expansion of the wiring board 4 and the substrate 1 during heating However, the coating-type conductive material 3 including the projection 13 can further suppress the generation of the cracks during heating

In the form of FIG. 4, one projection 13 is provided in a thickness direction. Thus, in the case of the one projection 13, the cured portion of the coating-type conductive material 3 can have a structure which is less likely to generate the cracks and is formed with an amount of the coating-type conductive material 3 minimized as much as possible, and give a conductive cured body having high conductivity and a high strength efficiently. The thickness direction is a direction of a thickness of the organic EL element.

In the case where one projection 13 is formed in the thickness direction when the coating-type conductive material 3 is cured, a vertex H of the projection 13 is preferably within 20% of a distance between the substrate 1 and the wiring board 4 from a middle C of the distance. More specifically, when the distance between the substrate 1 and the wiring board 4 is defined as 1, the vertex H of the projection 13 is disposed within a range C1 which is 3/10 to 7/10 of the distance from the substrate 1. The vertex H of the projection 13 is disposed near the middle position between the substrate 1 and the wiring board 4, and thereby the cracks can be decreased, and conductive connectivity can be improved.

The projection 13 is preferably inside an end edge of a contact portion between the coating-type conductive material 3 and the wiring connecting electrode 11, and inside an end edge of a contact portion between the coating-type conductive material 3 and the electrode lead-out part 5. In this case, as shown in FIG. 4, a position H1 of the vertex H of the projection 13 is disposed inside a position E2 of the end edge of the contact portion between the coating-type conductive material 3 and the wiring connecting electrode 11, and inside a position E1 of the end edge of the contact portion between the coating-type conductive material 3 and the electrode lead-out part 5. Thus, the projection 13 is disposed inside, and thereby the projection 13 of the cured coating-type conductive material 3 can be prevented from protruding to the side, to efficiently improve a light emitting area ratio. When the coating-type conductive material 3 protrudes to the side, the coating-type conductive material 3 may be brought into contact with other members, and damaged, or may be brought into contact with a conductive member to cause electric short circuit. However, the projection 13 which is prevented from protruding to the side as much as possible can suppress generation of damage and poor conduction. The position H1 of the vertex H of the projection 13 represents a position in a lateral direction. The positions E1 and E2 of the end edge represent positions outside the contact portions. In the form of FIG. 4, the positions E1 and E2 which are positions of the end edges of the coating-type conductive material 3 are located at the substantially same position in the lateral direction. Needless to say, the positions E1 and E2 may be located at different positions in the lateral direction.

The coating-type conductive material 3 preferably includes a boundary portion being in contact with the wiring connecting electrode 11 at an acute inclination angle θ2. Thereby, the coating-type conductive material 3 and the wiring connecting electrode 11 can be brought into contact with each other in a larger area in the boundary portion, and the conductive connectivity can be improved. In this case, the conductive cured body, which is the cured coating-type conductive material 3, has the boundary portion which is in contact with the wiring connecting electrode 11 and has an inclined surface inclined inward to the wiring board 4. The coating-type conductive material 3 preferably includes a boundary portion being in contact with the electrode lead-out part 5 at an acute inclination angle θ1. Thereby, the coating-type conductive material 3 and the electrode lead-out part 5 can be in contact with each other in a larger area in the boundary portion, and thus the conductive connectivity can be improved. In this case, the conductive cured body, which is the cured coating-type conductive material 3, has the boundary portion which is in contact with the electrode lead-out part 5 and has an inclined surface inclined inward to the substrate 1. In the present form, both the angles θ1 and θ2 in the boundary portions of the coating-type conductive material 3 are the acute inclination angles. Therefore, it is possible to efficiently improve the conductive connectivity in both the wiring connecting electrode 11 and the electrode lead-out part 5 while decreasing the amount of the coating-type conductive material 3 as much as possible. The inclination angles θ1 and θ2 are not particularly limited, and can be 10 to 80°, for example. In the present form, the coating-type conductive material 3 has a W-shaped cross-sectional surface. The W-shaped cross-sectional surface makes it possible to give both the inclined surface in the end in the thickness direction and the projection 13.

The organic EL element of the form of FIG. 4 can be produced by applying the coating-type conductive material 3 by injecting from the side with a jet type dispenser, for example. The jet type dispenser can inject the coating-type conductive material 3 in a droplet state. Therefore, the injected coating-type conductive material 3 abuts against a side wall of the sealing member 2, and accordingly the projection 13 can be formed. The projection 13 can be injected to the middle position C and disposed within 20% of the distance between the substrate 1 and the wiring board 4 from a middle position C between the substrate 1 and the wiring board 4. The projection 13 can be located inside the end edge of the boundary portion between the coating-type conductive material 3 and the electrode lead-out part 5, and inside the end edge of the boundary portion between the coating-type conductive material 3 and the wiring connecting electrode 11, by the coating-type conductive material 3 being appropriately adjusted in an amount and injected to the middle position C. The conductive cured body can have the boundary portion between the coating-type conductive material 3 and the electrode lead-out part 5 and the boundary portion between the coating-type conductive material 3 and the wiring connecting electrode 11 that are inclined at an acute angle, by the coating-type conductive material 3 being adjusted in an amount and injected to the middle position C Wettability of the coating-type conductive material 3 is useful for forming the inclined surface in the cured portion of the coating-type conductive material 3. More specifically, the coating-type conductive material 3 spreads and arrives at an electrode material under a function of surface tension or adsorption force, and accordingly the inclined surface can be formed in the end of the coating-type conductive material 3 in the thickness direction.

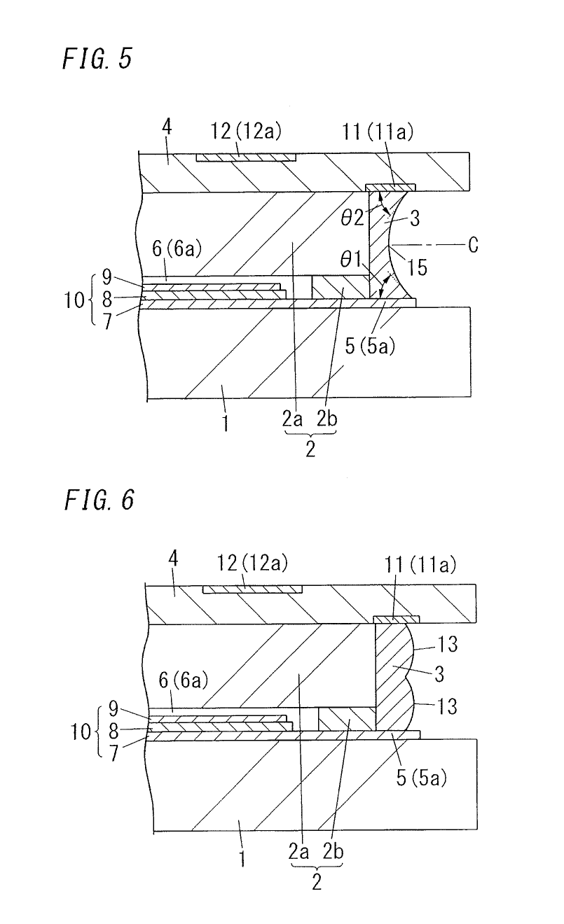

FIG. 5 shows yet another example of an organic EL element in an embodiment. FIG. 5 is an enlarged view of a vicinity of a position of a coating-type conductive material 3 connecting an electrode lead-out part 5 and a wiring connecting electrode 11 to each other. The present form has the almost same structure as the structure of the form of FIGS. 1 and 2 except that the cured coating-type conductive material 3 has a different shape.

In the form of FIG. 5, a conductive cured body, which is the cured coating-type conductive material 3, does not include the projection 13 in contrast to the case of the form of FIG. 4. The cured coating-type conductive material 3 has a recessed side surface having a recess 15. Therefore, as compared with the coating-type conductive material 3 including the projection 13, the coating-type conductive material 3 can be decreased in an amount, and can provide conductive connection in a small amount Similarly as in the form of FIG. 4, the coating-type conductive material 3 includes a boundary portion brought into contact with the wiring connecting electrode 11 at an acute inclination angle θ2 and a boundary portion being in contact with the electrode lead-out part 5 at an acute inclination angle θ1. Thereby, the coating-type conductive material 3 can include the boundary portions being in contact with the wiring connecting electrode 11 and the electrode lead-out part 5 in a larger area, and improve conductive connectivity efficiently. In the present form, the coating-type conductive material 3 has a U-shaped cross-sectional surface. The U-shaped cross-sectional surface can provide both an inclined surface in an end in a thickness direction and the recess 15.

The organic EL element of the form of FIG. 5 can be produced by inserting a nozzle of an air type dispenser between a substrate 1 and a wiring board 4 from a side of the element, and by discharging the coating-type conductive material 3 to be applied from a nozzle tip, for example. The coating-type conductive material 3 which is injected by the air type dispenser can spread from a nozzle portion. The injected coating-type conductive material 3 abuts against a side wall of a sealing member 2 and spreads to both sides of the substrate 1 and the wiring board 4, and a middle portion of the coating-type conductive material 3 is indented to form the recess 15, and accordingly the coating-type conductive material 3 is formed. In this case, the coating-type conductive material 3 is preferably injected to a middle position C between the substrate 1 and the wiring board 4. Thereby, the coating-type conductive material 3 can be indented at a position closer to the middle position C, and the coating-type conductive material 3 can spread in a well-balanced manner to both sides of the substrate 1 and the wiring board 4 so as to prevent the uneven distribution of the coating-type conductive material 3, to improve conductivity. The conductive cured body can have the boundary portion between the coating-type conductive material 3 and the electrode lead-out part 5 and the boundary portion between the coating-type conductive material 3 and the wiring connecting electrode 11 which are inclined at an acute angle, when the coating-type conductive material 3 is adjusted in an amount and injected to the middle position C.

FIG. 6 shows yet another example of an organic EL element in an embodiment. FIG. 6 is an enlarged view of a vicinity of a position of a coating-type conductive material 3 connecting an electrode lead-out part 5 and a wiring connecting electrode 11 to each other. The present form has the almost same structure as the structure of the form of FIGS. 1 and 2 except that the cured coating-type conductive material 3 has a different shape.

In the form of FIG. 6, the coating-type conductive material 3, which is cured, includes a plurality of projections 13. Thus, as a preferable form, the plurality of projections 13 are provided in a thickness direction. Thereby, conductive connectivity can be improved, and generation of cracks can be suppressed. A conductive cured body which is the cured coating-type conductive material 3 has a large thickness, depending on the plurality of projections 13, and a surface of a side part of the conductive cured body can be further planarized, and thereby the conductive cured body can be less likely to generate cracks, and can have high electric connectivity. The coating-type conductive material 3 including the plurality of projections 13 can reliably provide electrical connection even if a sealing member 2 has a large thickness and a distance between a substrate 1 and a wiring board 4 in the thickness direction is large. The thickness direction is a direction of a thickness of the organic EL element.

In the present form, two projections 13 are formed in the thickness direction. More specifically, one of the projections 13 is closer to the substrate 1 than the other of the projections 13, and the other is closer to the wiring board 4 than the one. Thus, the two projections 13 can provide electrical connection at high conductivity with an amount of the coating-type conductive material 3 minimized as much as possible. The number of the projections 13 in the thickness direction is not limited to 2, and may be 3 or 4 or more. However, an increase in the number of the projections 13 may cause waste of the coating-type conductive material 3 and protrusion of the coating-type conductive material 3 to a side. Therefore, the number of the projections 13 may be 5 or less, for example.

In a case of the two projections 13 in the thickness direction, it is preferable that one of the projections 13 is between the substrate 1 and a middle position that is between the substrate 1 and the wiring board 4, and the other is between the wiring board 4 and the middle position. The projections 13 provided without the uneven distribution can improve the conductive connectivity efficiently. In the present form, the coating-type conductive material 3 has a wavelike cross-sectional surface. The wavelike cross-sectional surface can provide the coating-type conductive material 3 which includes the plurality of projections 13 arranged in the thickness direction.

In the form of FIG. 6, vertexes of the projections 13 are located outside end edges of portions of the coating-type conductive material 3 being in contact with the electrode lead-out part 5 and the wiring connecting electrode 11. Similarly as in the form of FIG. 4, the vertexes of the projections 13 may be located inside the end edges. The coating-type conductive material 3 includes boundary portions being in contact with the electrode lead-out part 5 and the wiring connecting electrode 11 at an obtuse angle in a state where the coating-type conductive material 3 laterally swells. Similarly as in the form of FIG. 4, the coating-type conductive material 3 may include boundary portions being in contact with the electrode lead-out part 5 and the wiring connecting electrode 11 at an acute inclination angle.

The organic EL element of the form of FIG. 6 can be produced by injecting the coating-type conductive material 3 to be applied from the side of the element while changing an application position of the coating-type conductive material 3 in the thickness direction with a jet type dispenser, for example. The jet type dispenser can inject the coating-type conductive material 3 in a droplet state. Therefore, the injected coating-type conductive material 3 abuts against a side wall of the sealing member 2, and forms the projections 13. In this case, the coating-type conductive material 3 is injected from two positions, and accordingly the plurality of (two) projections 13 of the coating-type conductive material 3 are formed in a well-balanced manner in the thickness direction. The two positions are a position which is at about ¼ of a distance between the substrate 1 and the wiring board 4 from the substrate 1, and a position which is at about ¾ of the distance from the substrate 1.

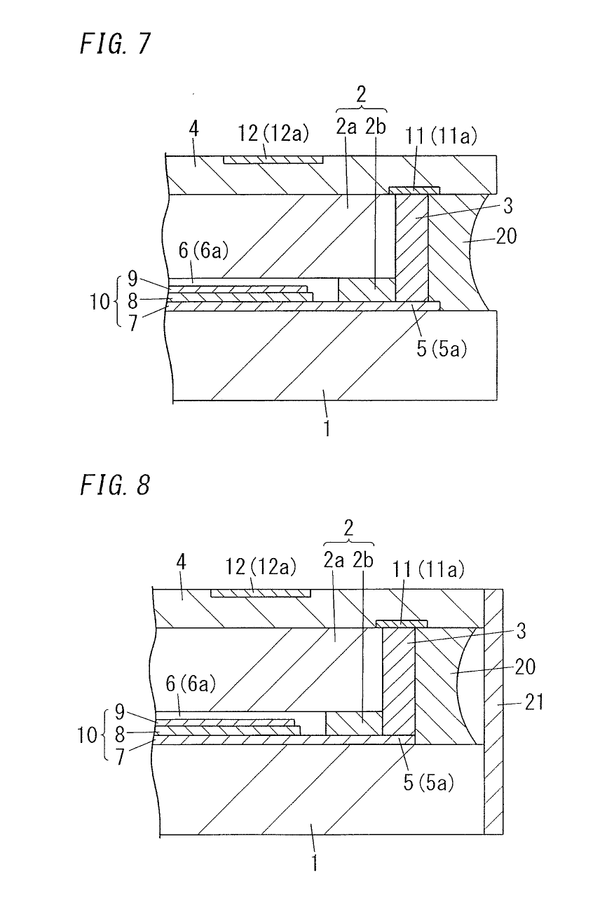

FIG. 7 shows yet another example of an organic EL element in an embodiment. FIG. 7 is an enlarged view of a vicinity of a position of a coating-type conductive material 3 connecting an electrode lead-out part 5 and a wiring connecting electrode 11 to each other. The present form has the almost same structure as the structure of the form of FIGS. 1 and 2 except that a protector 20 is provided.

The coating-type conductive material 3 is preferably coated with the protector 20 made of a resin. In the form of FIG. 7, the coating-type conductive material 3 is coated with the protector 20. More specifically, a conductive connection portion obtained by curing the coating-type conductive material 3 is coated with the protector 20. The protector 20 covers the coating-type conductive material 3, thereby suppressing divisions or cracks of the coating-type conductive material 3 by damaging. Therefore, connection reliability can be improved. Because the protector 20 is made of a resin, the coating-type conductive material 3 can be easily coated with the resin. The protector 20 preferably has insulation properties. The protector 20 has insulation properties and accordingly it is possible to secure an insulating distance of the coating-type conductive material 3 easily, and to improve connection reliability. The protector 20 is made of a resin, and accordingly the insulation properties can be easily applied to the protector 20.

The protector 20 is disposed between a substrate 1 and a wiring board 4. The protector 20 may be provided so as to fill a clearance between the substrate 1 and the wiring board 4. The protector 20 preferably sticks to the coating-type conductive material 3. The protector 20 preferably sticks to the substrate 1. The protector 20 preferably sticks to the wiring board 4. The protector 20 may stick to the substrate 1 or the wiring board 4, or may not stick to the substrate 1 and the wiring board 4. However, the protector 20 preferably sticks to both the substrate 1 and the wiring board 4. The protector 20 is disposed at least at a position of the coating-type conductive material 3 between the substrate 1 and the wiring board 4. The protector 20 may be disposed over a total length of an end of the organic EL element on which the coating-type conductive material 3 is located. The protector 20 may be disposed over an outer periphery of the organic EL element.

In FIG. 7, the protector 20 has a width (a length in a lateral direction) in an end thereof in a thickness direction larger than a width in a center thereof in the thickness direction. The protector 20 has a larger width toward both ends in the thickness direction. Thereby, adhesiveness between the substrate 1 and the wiring board 4 can be improved. The protector 20 has a U-shaped surface.

The protector 20 may be formed of an appropriate resin. Examples of the resin include an epoxy resin, an acrylic resin, a phenolic resin, polyolefin, and unsaturated polyester. The resin may be a thermosetting resin, a photo-curable resin, and/or a thermoplastic resin.

The organic EL element of the form of FIG. 7 can be produced by, for example, disposing the coating-type conductive material 3 between the electrode lead-out part 5 and the wiring connecting electrode 11, then disposing a flowable resin as a material for the protector 20 between the substrate 1 and the wiring board 4, and then curing the resin. The resin can be applied with an appropriate applicator such as a jet type dispenser. Alternatively, a resin body as a molded body may be disposed in the clearance between the substrate 1 and the wiring board 4, to form the protector 20. The protector 20 formed of a previously molded resin body preferably sticks to the coating-type conductive material 3 with an adhesive agent or the like interposed between the protector 20 and the coating-type conductive material 3. The resin for the protector 20 is preferably applied after the coating-type conductive material 3 is cured. Thereby, the protector 20 can be provided without damaging the coating-type conductive material 3. Needless to say, in the case where the coating-type conductive material 3 and the resin for the protector 20 do not intermingle with each other before cured, the following procedure may be performed: the coating-type conductive material 3 is disposed; the resin of the protector 20 is then disposed in a state where the coating-type conductive material 3 is not cured; and the coating-type conductive material 3 and the resin for the protector 20 are simultaneously cured. In such a case, the coating-type conductive material 3 and the resin of the protector 20 can be efficiently cured. The resin for the protector 20 is preferably disposed so that the coating-type conductive material 3 is not damaged.

In the form of FIG. 7, as an example, the protector 20 is provided to protect the coating-type conductive material 3 having the shape shown in FIG. 2. However, the protector 20 may be provided in any of coating-type conductive materials 3 of the above-described forms. Both an insulating wall 14 and the protector 20 may also be provided. In such a case, the protector 20 may be disposed outside the insulating wall 14.

FIG. 8 shows yet another example of an organic EL element in an embodiment. FIG. 8 is an enlarged view of a vicinity of a position of a coating-type conductive material 3 connecting an electrode lead-out part 5 and a wiring connecting electrode 11 to each other. The present form has the almost same structure as the structure of the form of FIGS. 1 and 2 except that a protector 20 and an insulating sheet 21 are provided.

The organic EL element preferably includes the insulating sheet 21 sticking to a side part of at least one of a substrate 1 and a wiring board 4, and covering a side of the coating-type conductive material 3. The insulating sheet 21 can secure an insulating distance easily and improve reliability The insulating sheet 21 can prevent the coating-type conductive material 3 from exposing to the outside easily. In the form of FIG. 8, the coating-type conductive material 3 is covered with the protector 20, and the side of the coating-type conductive material 3 covered with the protector 20 is further covered with the insulating sheet 21. The protector 20 may be the protector described in the form of FIG. 7. The form of FIG. 8 is provided by adding the insulating sheet 21 to the form of FIG. 7.

The insulating sheet 21 is made of a sheet material having electric insulation properties. The insulating sheet 21 may include a resin sheet. Examples of the resin sheet include, but are not particularly limited to, a PET sheet and a PEN sheet. The term PET is polyethylene terephthalate, and the term PEN is polyethylene naphthalate.

The insulating sheet 21 may stick to at least one of the substrate 1 and the wiring board 4. More specifically, the insulating sheet 21 may stick to only the substrate 1, and may stick to only the wiring board 4. The insulating sheet 21 may stick to both the substrate 1 and the wiring board 4. The insulating sheet 21 more preferably sticks to both the substrate 1 and the wiring board 4. Thereby, a space between the substrate 1 and the wiring board 4 is blocked, and accordingly insulation properties can be further improved. When the insulating sheet 21 sticks to only one of the substrate 1 and the wiring board 4, the insulating sheet 21 is preferably in contact with the other of the substrate 1 and the wiring board 4. Thereby, the insulation properties can be improved. Sticking of the insulating sheet 21 may be performed with an adhesive agent. The insulating sheet 21 may be in contact with both the substrate 1 and the wiring board 4.

In FIG. 8, the insulating sheet 21 sticks to both the substrate 1 and the wiring board 4. Preferably, the insulating sheet 21 does not protrude from the substrate 1 in a thickness direction. A side of the substrate 1 is a light-emitting surface side. When the insulating sheet 21 is provided to protrude from a surface of the substrate 1, design properties may be decreased. Part of the insulating sheet 21 near the wiring board 4 may protrude from an external surface of the wiring board 4, or may not protrude from the external surface. The insulating sheet 21 may be bent inside and stick to the surface of the wiring board 4.

In the form of FIG. 8, an example including both the protector 20 and the insulating sheet 21 is shown. However the protector 20 is non-essential. More specifically, the insulating sheet 21 may be added to the form shown in FIG. 2. Also in such a case, the insulating distance can be easily secured. The side of the coating-type conductive material 3 can be protected.

When both the protector 20 and the insulating sheet 21 are provided, the protector 20 may fill a space between the insulating sheet 21 and the coating-type conductive material 3. Thereby, protection properties can be improved. The insulating sheet 21 may stick to the protector 20 made of an adhesive resin. Thereby, the insulating sheet 21 can be disposed and sticks to the protector 20 easily.

The insulating sheet 21 is disposed on a side part of the organic EL element. The insulating sheet 21 is disposed at least at a position of a side part of the coating-type conductive material 3. The insulating sheet 21 may be disposed over a total length of an end of the organic EL element on which coating-type conductive material 3 is disposed. The insulating sheet 21 may be disposed over an outer periphery of the organic EL element.

The organic EL element of the form of FIG. 8 can be produced by, for example, covering the coating-type conductive material 3 with the protector 20, and then making the insulating sheet 21 stick to one or both of the substrate 1 and the wiring board 4. The insulating sheet 21 may be a long sheet extending along the end of the organic EL element. The insulating sheet 21, which an adhesive agent is applied to, may stick to one or both of the substrate 1 and the wiring board 4. The insulating sheet 21 may stick to one or both of the substrate 1 and the wiring board 4 which an adhesive agent is applied to. Alternatively, in the case of using the resin contained in the protector 20 functioning as an adhesive agent, the insulating sheet 21 may stick to the protector 20. In such a case, the resin contained in the protector 20 is preferably cured after the insulating sheet 21 is pasted. When the protector 20 is not provided, the insulating sheet 21 can be disposed by being made to stick to one or both of the substrate 1 and the wiring board 4 after the coating-type conductive material 3 is disposed.

The form of FIG. 8 is provided as an example by adding the insulating sheet 21 to the form of FIG. 7. The insulating sheet 21 can be also applied to any of the above-described forms. For example, the organic EL element may include both the insulating wall 14 and the insulating sheet 21 without the protector 20. The organic EL element may also include the protector 20, the insulating wall 14, and the insulating sheet 21. The coating-type conductive material 3 may have any of the above-described shapes.

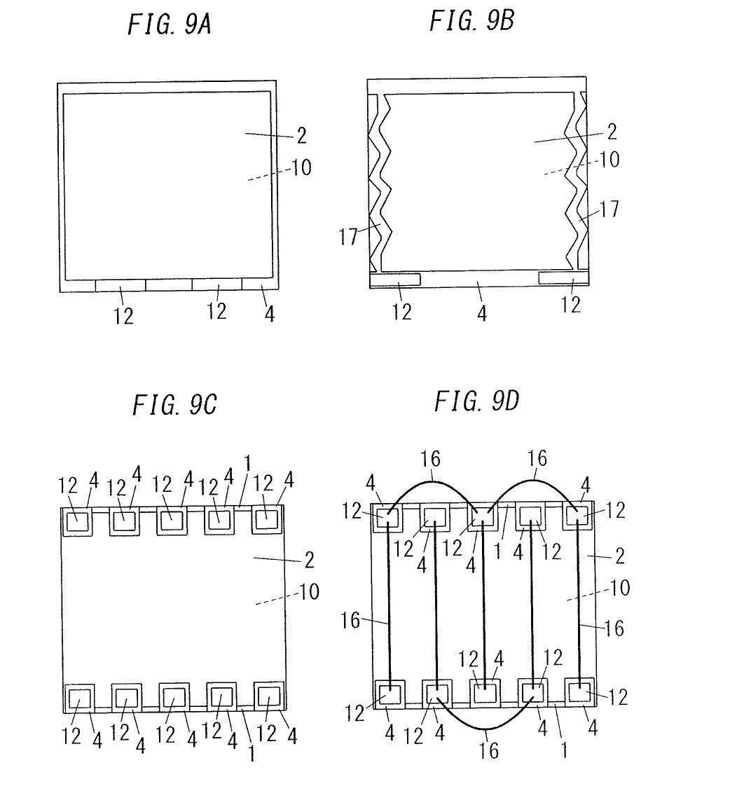

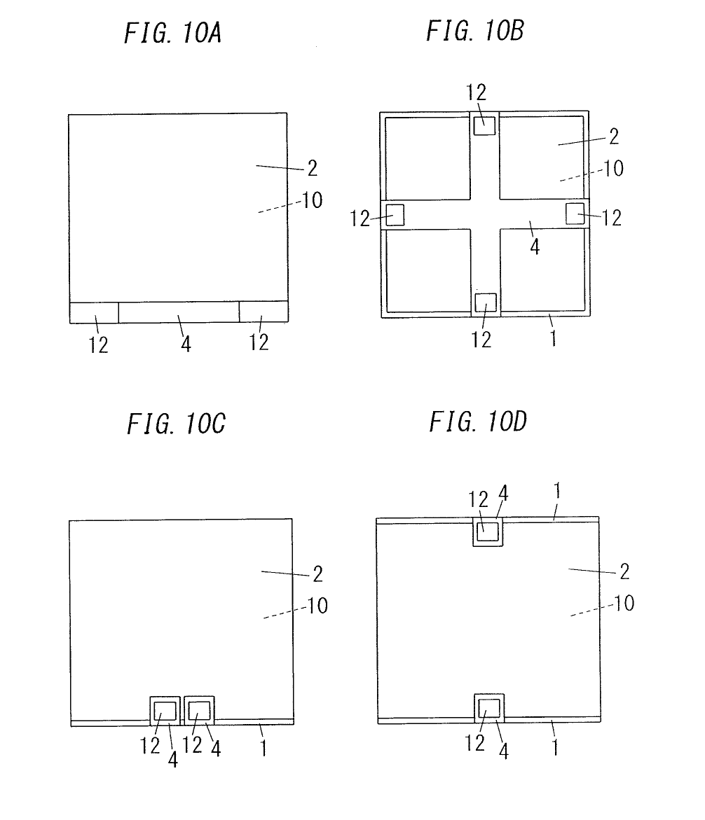

FIGS. 9A to 9D and FIGS. 10A to 10D show examples of an organic EL element in the embodiment, and show examples of a wiring board 4 in forms. FIGS. 9A to 9D are collectively referred to as FIG. 9. FIGS. 10A to 10D are collectively referred to as FIG. 10. Each form of FIGS. 9 and 10 shows the organic EL element, when viewed as a plane from the wiring board 4.

In the form shown in FIG. 1, the wiring board 4 covers the whole surface of the sealing member 2. Depending on a material for the wiring board 4, a difference between thermal expansibilities of the wiring board 4 and the substrate 1 or the sealing member 2 may generate cracks in the cured portion of the coating-type conductive material 3 during heating. Generally, an insulating resin material tends to have a coefficient of thermal expansion higher than a coefficient of thermal expansion of a glass material. The difference between the coefficients of thermal expansion causes different expansibilities during heating, which is apt to generate cracks. Therefore, each of FIGS. 9 and 10 shows a preferable form, and a wiring board 4 has a size smaller than a size of a sealing member 2 in a plane view, and a wiring board 4 is attached to the sealing member 2, and an external electrode pad 12 is located on an opposite side of the wiring board 4 from the sealing member 2. Also in such a case, by making the wiring board 4 protrude to an external side from the sealing member 2, a wiring connecting electrode 11 on a surface of the wiring board 4, located on an opposite side of the wiring board 4 from the external electrode pad 12, can be provided to face an electrode lead-out part 5.

In each form of FIGS. 9A to 9D, there may be an external electrode pad 12 for electrically conducting an organic light emitter 10 having the same stacked pattern as the pattern shown in FIG. 1. More specifically, three first electrode lead-out parts 5a and two second electrode lead-out parts 5b are disposed on each of both side parts of the element having a rectangular shape. The electrode lead-out part 5 has a pattern in which the electrode lead-out parts 5a and 5b are alternately disposed, thereby being subjected to conductive connection. In each form of FIG. 9, the conductive connection is enabled in the organic light emitter 10 having the same pattern as the pattern of FIG. 1. When electrical current is applied from both ends, an in-plane current distribution is further uniformed, and more uniform surface emitting can be obtained.

FIGS. 9A and 9B show forms including a frame-shaped wiring board 4.

FIG. 9A shows the rectangular frame-shaped wiring board 4 having a through-hole. The through-hole is formed by boring a middle part of the wiring board 4 shown in the form of FIG. 1. Therefore, a surface of the sealing member 2 (sealing substrate 2a) is exposed in the middle part of the wiring board 4. The wiring board 4 sticks to a peripheral part of the sealing member 2. A plurality of wiring connecting electrodes 11 are provided at positions corresponding to the electrode lead-out part 5. The wiring connecting electrodes 11 are electrically collected by routing the wire (conductive wiring 4c), and integrated in the external electrode pad 12 as an extraction electrode.

In the present form, the wiring board 4 is not disposed in the middle part of the element. Therefore the whole surface of the wiring board 4 is not thermally expanded during heating, and a degree of the thermal expansion can be decreased, which can suppress generation of cracks in a coating-type conductive material 3 by the thermal expansion.

In FIG. 9B, the wiring board 4 shown in the form of FIG. 9A is modified to the follows. The wiring board 4 includes a thermal expansion absorption part 17 to absorb thermal expansion, which is located on an end of the wiring board 4 without a wiring connecting electrode 11 and has a zigzag type waveform shape in a plane view. The waveform-shaped thermal expansion absorption part 17 may have a wiring structure (conductive wiring 4c or the like) electrically connecting the wiring connecting electrode 11 and an external electrode pad 12 to each other.

Since a part of the wiring board 4 is formed in a waveform shape in the present form, the wave type structure can absorb thermal expansion of the wiring board 4 during heating, which can decrease the degree of the whole thermal expansion. Therefore, generation of cracks in a coating-type conductive material 3 by the thermal expansion can be suppressed.

FIGS. 9C and 9D show forms including individualized wiring boards 4. Among these, as an example, FIG. 9C shows wiring boards 4, each of which includes a wiring connecting electrode 11 and an external electrode pad 12. The wiring boards 4 stick to a sealing member 2 so as to correspond to electrode lead-out parts 5, respectively.

In the form of FIG. 9C, a size of the wiring board 4 can be decreased to a minimum size required for connection to an external power source. Accordingly the wiring board 4 on the sealing member 2 can have a small size, and is not required to have a size over the total length of the sealing member 2. Therefore, an area of the wiring board 4 thermally expanded during heating can be decreased, and generation of cracks in a coating-type conductive material 3 due to the thermal expansion can be suppressed by decreasing the degree of the thermal expansion.

In FIG. 9D, a plurality of external electrode pads 12 are electrically connected by electrical wirings 16 such as wires in the form of FIG. 9C. The electrical wirings 16 are connected so that a first electrode 7 and a second electrode 9 are not short-circuited.

Also in the form of FIG. 9D, a size of a wiring board 4 can be decreased to a minimum size required for connecting the wiring board 4 to an external power source. Because wiring boards 4 are not electrically connected with each other in the form of FIG. 9C, it is necessary to separately supply power to the external electrode pad 12 of each wiring board 4. On the other hand, because electrodes to be connected to the external power source are collected by the electrical wirings 16 in the form of FIG. 9D, feeding points can be decreased. Therefore, an organic EL element can provide easy power feeding.

In each form of FIGS. 10A to 10D, conductive connection can be provided as follows. An organic light emitter 10 has a stacked pattern, which differs from the stacked pattern shown in FIG. 1, by modifying a pattern shape of an electrode lead-out part 5 in order to unevenly dispose electrode lead-out parts 5 in an end.

FIG. 10A shows a form including a strip wiring board 4. FIG. 10B shows a form including a cross-shaped wiring board 4.

In FIG. 10A, the strip wiring board 4 sticks to a side part of a sealing member 2. Therefore, a surface of the sealing member 2 (sealing substrate 2a) is exposed in a middle part and other side parts of the sealing member 2. A plurality of electrode lead-out parts 5 can be provided on an end (side part) on which the wiring board 4 is disposed. A plurality of wiring connecting electrodes 11 are disposed at positions corresponding to the electrode lead-out parts 5. The wiring connecting electrodes 11 are collected by routing of wires and integrated to an external electrode pad 12.

Since an area of the wiring board 4 can be decreased in the present form, a degree of thermal expansion of the wiring board 4 during heating can be decreased, and generation of cracks in a coating-type conductive material 3 due to the thermal expansion can be suppressed. The electrode lead-out parts 5 only on one side part can increase a light emitting region on the other side parts and provide a further increase in a light emitting area rate.

In FIG. 10B, the wiring board 4 has a cross shape. The wiring board 4 is attached to the sealing member 2 so that a center of the cross shape is located at a substantial center of a sealing member 2. An electrode lead-out part 5 is disposed on a middle portion of each of four side parts of the sealing member 2 having a rectangular shape. A wiring connecting electrode 11 is disposed at a position corresponding to the electrode lead-out part 5. The wiring connecting electrode 11 is electrically connected to an external electrode pad 12.

Since an area of the wiring board 4 can be decreased in the present form, a degree of thermal expansion of the wiring board 4 during heating can be decreased, and generation of cracks in a coating-type conductive material 3 due to the thermal expansion can be suppressed. A corner part of the rectangular sealing member 2 is apt to be subject to influence of the thermal expansion. Since the wiring board 4 is not disposed on the corner part of the sealing member 2 in the present form, the generation of the cracks in the coating-type conductive material 3 can be further suppressed.

FIGS. 10C and 10D show forms including individualized wiring boards 4.

In the form of FIG. 10C, electrode lead-out parts 5 are unevenly formed on one of four side parts of the sealing member. A total of two electrode lead-out parts 5 are formed. One of the two electrode lead-out parts 5 is electrically conducted to a first electrode 7, and the other is electrically conducted to a second electrode 9. The two electrode lead-out parts 5 are closer to a middle portion of the one of the four side parts. A wiring board 4 includes a wiring connecting electrode 11 to correspond to the electrode lead-out part 5, and an external electrode pad 12 is disposed in a surface of the wiring board 4.

A change in thermal expansion in an end is generally larger than a change in thermal expansion in the middle portion. Therefore, as the position of the wiring board 4 is closer to a corner part of a sealing member 2, the wiring board 4 is apt to be further subjected to a change in thermal expansion, which may generate cracks in a coating-type conductive material 3. However, in the present form, the wiring board 4 is disposed on a middle part of one side of the sealing member 2 in a plane view, and is not disposed on the corner part of the sealing member 2. Therefore, a degree of thermal expansion of the wiring board 4 is further decreased during heating, and thereby generation of cracks in a coating-type conductive material 3 due to the thermal expansion can be suppressed. The individualized wiring board 4 can decrease an area of the wiring board 4, and suppress an influence of the thermal expansion, and provide external electrode pad 12 efficiently.

In FIG. 10D, one of first and second electrode lead-out parts 5 is disposed on one of four side parts of the sealing member, and the other is disposed on a side part facing the side part. The respective electrode lead-out parts 5 are disposed on middle portions of side parts. A wiring board 4 includes a wiring connecting electrode 11 to correspond to the electrode lead-out part 5, and an external electrode pad 12 is disposed in a surface of the wiring board 4.

Also in the present form, the wiring board 4 is disposed on a middle part of one side of a sealing member 2 in a plane view, and is not disposed on a corner part of the sealing member 2. Therefore, a degree of thermal expansion of the wiring board 4 is further decreased during heating, and thereby generation of cracks in a coating-type conductive material 3 by the thermal expansion can be suppressed. The individualized wiring board 4 can decrease an area of the wiring board 4, suppress an influence of the thermal expansion, and provide the external electrode pad 12 efficiently. In the form of FIG. 10D, the wiring board 4 can be provided closer to the middle position as compared with the form of FIG. 10C, and thereby the influence of the thermal expansion can be decreased and the generation of the cracks can be suppressed.

An illuminating apparatus can be provided by using the above-mentioned organic EL element. The illuminating apparatus includes the organic EL element. Thereby, the illuminating apparatus can have high reliability. The illuminating apparatus may include a plurality of organic EL elements disposed in a planar form. When the plurality of organic EL elements are disposed in a planar form, a boundary line between the adjacent organic EL elements can be made unnoticeable. The illuminating apparatus may be a planar illumination body including one organic EL element. The illuminating apparatus may have a wiring structure for supplying power to the organic EL element. The illuminating apparatus may include a case supporting the organic EL element. The illuminating apparatus may include a plug electrically connecting the organic EL element and a power source to each other. The illuminating apparatus can have a panel like shape. Because the illuminating apparatus can have a reduced thickness, a space-saving light device can be provided.

### REFERENCE SIGNS LIST

1 Substrate
2 Sealing member
2a Sealing substrate
2b Sealing wall
3 Coating-type conductive material
4 Wiring board
4a Insulating layer
4b Resist layer
4c Conductive wiring
4d Penetration wiring
5 Electrode lead-out part
6 Sealing clearance
6a Sealing filler
7 First electrode
8 Organic light-emitting layer
9 Second electrode
10 Organic light emitter
11 Wiring connecting electrode
12 External electrode pad
13 Projection
14 Insulating wall
15 Recess
16 Electrical wiring
20 Protector
21 Insulating sheet

1. An organic electroluminescent element comprising:
a substrate;
an organic light emitter including a first electrode, an organic light-emitting layer, and a second electrode, the first electrode, the organic light-emitting layer and the second electrode being located in this order;
a sealing member covering the organic light emitter;
an electrode lead-out part provided on a surface of an end of the substrate, the electrode lead-out part being externally led out from the sealing member, the electrode lead-out part being electrically connected to at least one of the first electrode and the second electrode; and
a wiring board provided on an opposite side of the sealing member from the substrate, the wiring board having a surface facing the substrate, the wiring board including a wiring connecting electrode in the surface, the wiring connecting electrode facing the electrode lead-out part,
the wiring board having an opposite surface from the surface which the wiring connecting electrode is in, the wiring board including an external electrode pad in the opposite surface, the external electrode pad being electrically connected to the wiring connecting electrode,
the wiring connecting electrode and the electrode lead-out part being electrically connected to each other by a coating-type conductive material.

2. The organic electroluminescent element according to claim 1, wherein
a cured portion provided by curing the coating-type conductive material includes at least one projection laterally swelling.

3. The organic electroluminescent element according to claim 2, wherein
the at least one projection includes a plurality of projections in a thickness direction of the organic electroluminescent element.

4. The organic electroluminescent element according to claim 2, wherein
the at least one projection includes a projection in a thickness direction of the organic electroluminescent element, and a vertex of the projection is within 20% of a distance between the substrate and the wiring board from a middle of the distance.

5. The organic electroluminescent element according to claim 2, wherein
the at least one projection is inside an end edge of a contact portion between the cured portion of the coating-type conductive material and the wiring connecting electrode, and inside an end edge of a contact portion between the cured portion of the coating-type conductive material and the electrode lead-out part.

6. The organic electroluminescent element according to claim 1, wherein
the cured portion of the coating-type conductive material includes a boundary portion brought into contact with the wiring connecting electrode at an acute inclination angle and a boundary portion brought into contact with the electrode lead-out part at an acute inclination angle.

7. The organic electroluminescent element according to claim 1, further comprising an insulating wall outside the electrode lead-out part on the substrate.

8. The organic electroluminescent element according to claim 1, wherein
the cured portion of the coating-type conductive material is coated with a protector made of a resin.

9. The organic electroluminescent element according to claim 1, further comprising an insulating sheet sticking to a side part of at least one of the substrate and the wiring board, and covering a side of the cured portion of the coating-type conductive material.

10. An illuminating apparatus comprising the organic electroluminescent element according to claim 1.

11. The organic electroluminescent element according to claim 3, wherein
the at least one projection is inside an end edge of a contact portion between the cured portion of the coating-type conductive material and the wiring connecting electrode, and inside an end edge of a contact portion between the cured portion of the coating-type conductive material and the electrode lead-out part.

12. The organic electroluminescent element according to claim 4, wherein
the at least one projection is inside an end edge of a contact portion between the cured portion of the coating-type conductive material and the wiring connecting electrode, and inside an end edge of a contact portion between the cured portion of the coating-type conductive material and the electrode lead-out part.

13. The organic electroluminescent element according to claim 2, wherein
the cured portion of the coating-type conductive material includes a boundary portion brought into contact with the wiring connecting electrode at an acute inclination angle and a boundary portion brought into contact with the electrode lead-out part at an acute inclination angle.

14. The organic electroluminescent element according to claim 5, wherein
the cured portion of the coating-type conductive material includes a boundary portion brought into contact with the wiring connecting electrode at an acute inclination angle and a boundary portion brought into contact with the electrode lead-out part at an acute inclination angle.

15. The organic electroluminescent element according to claim 2, further comprising an insulating wall outside the electrode lead-out part on the substrate.

16. The organic electroluminescent element according to claim 2, wherein
the cured portion of the coating-type conductive material is coated with a protector made of a resin.

17. The organic electroluminescent element according to claim 2, further comprising an insulating sheet sticking to a side part of at least one of the substrate and the wiring board, and covering a side of the cured portion of the coating-type conductive material.

18. An illuminating apparatus comprising the organic electroluminescent element according to claim 2 and a case supporting the organic EL element.
